(19) United States
(12) Patent Application Publication
(10) Pub. No.: US 2014/0126166 A1
(43) Pub. Date: May 8, 2014

(54) METHOD OF FORMING SOLDER RESIST POST, METHOD OF MANUFACTURING ELECTRONIC DEVICE PACKAGE USONG SOLDER RESIST POST, AND ELECTRONIC DEVICE PACKAGE MANUFACTURED BY USING METHODS

(71) Applicant: SAMSUNG ELECTRO-MECHANICS CO., LTD., Suwon (KR)

(72) Inventors: Su Il Kim, Suwon (KR); Soon Jin Cho, Suwon (KR)

(73) Assignee: SAMSUNG ELECTRO-MECHANICS CO., LTD., Suwon (KR)

(21) Appl. No.: 13/730,408

(22) Filed: Dec. 28, 2012

(30) Foreign Application Priority Data
Nov. 8, 2012 (KR) 10-2012-0126126

(51) Int. Cl. H05K 13/00; H05K 1/18

(52) U.S. Cl. CPC H05K 13/00; H05K 1/18
USPC 361/760; 427/97.4; 156/247; 427/542; 156/242

(57) ABSTRACT

Disclosed herein is a method of forming a solder resist (SR) post, including: (A) forming an SR layer on a printed circuit board; (B) disposing a patterning film on an upper surface on the SR layer; (C) forming a plurality of openings in the patterning film or the SR layer; (D) filling SR ink in the openings and performing an exposure process to form a plurality of SR posts; (E) delaminating the patterning film; (F) removing an uncured portion of the SR ink on which the exposure process is performed; and (G) drying the plurality of SR posts.

### CROSS REFERENCE TO RELATED APPLICATION

This application claims the benefit of Korean Patent Application No. 10-2012-0126126, filed on Nov. 8, 2012, entitled “Method of forming Solder Resist Post, Method of Manufacturing Electronic Device Package Using Solder Resist Post, and Electronic Device Package Manufactured by Using Methods”, which is hereby incorporated by reference in its entirety into this application.

### BACKGROUND OF THE INVENTION

1. Technical Field

The present invention relates to a method of forming a solder resist (SR) post, a method of manufacturing an electronic device package, and an electronic device package manufactured by the methods.

2. Description of the Related Art

In electronic industrial fields, methods of forming miniaturized patterns have been continually developed. To this end, various technologies have been developed.

However, a packaging field has been developed most slowly in terms of miniaturized patterns due to various difficulties related to a connection between a silicon chip and a substrate. The packaging field has been significantly developed by using flip-chip technologies that replace conventional wire-bonding technologies. However, it is still difficult to miniaturize bump patterns.

Much research has been conducted to overcome these problems. As one recent research trends, Patent Document 1 below discloses a method of forming a bump by forming a dam so as to surround a region corresponding to the bump and printing conductive paste on the region corresponding to the bump.

In addition, there is a method using a solder resist (SR) dam that is formed to have a predetermined height by covering a secondary SR on a portion whereon a chip is formed in order to prevent underfill flow to allow the chip to be molded on a desired region during molding.

However, with regard to a specification of a conventional printed circuit board having a thin thickness less than 15 μm, many problems arise in terms of a conventional method of forming an SR dam due to a requirement for a thick SR dam having a height of 70 μm, and for example, process defects such as damaged and rolled products, warpage, solution contamination due to an excessive degree of SR development, or SR residues may occur.

In detail, conventionally, an SR dam is formed by laminating SR on a surface of a printed circuit board, on which a dam is to be formed, and exposing and developing the SR. In this regard, when the thickness of the SR dam is too large, while the SR is laminated on an ultrathin printed circuit board, the ultrathin printed circuit board becomes bent or torn which causes process defects, thereby causing warpage of the ultrathin printed circuit board.

In addition, even if lamination is performed with difficulty, exposures need to be performed 2 to 3 times in respects to the thickness of the SR dam. Even if exposing is performed, an amount of SR to be removed from a development region except for an exposure region of the SR dam is remarkably increased during development, and thus, development solution is seriously contaminated.

### PRIOR ART DOCUMENT

### Patent Document

(Patent Document 1) Korean Patent No. 10-0850763 (registered on Jul. 31, 2008)

### SUMMARY OF THE INVENTION

The present invention has been made in an effort to provide a method of forming a plurality of solder resist (SR) posts on a printed circuit board.

Further, the present invention has been made in an effort to provide a method of manufacturing an electronic device package by using an SR post.

Further, the present invention has been made in an effort to provide an electronic device package for packaging an electronic device by using an SR post.

According to a first preferred embodiment of the present invention, there is provided a method of forming a solder resist (SR) post, including: (A) forming an SR layer on a printed circuit board; (B) disposing a patterning film on an upper surface on the SR layer; (C) forming a plurality of openings in the patterning film or the SR layer; (D) filling SR ink in the openings and performing an exposure process to form a plurality of SR posts; (E) delaminating the patterning film; (F) removing an uncured portion of the SR ink on which the exposure process is performed; and (G) drying the plurality of SR posts.

Step (B) may include (B-1) tack-welding the patterning film on an upper surface of the SR layer by using a laminator; (B-2) removing a bubble between the SR layer and the patterning film by using a flattener; and (B-3) performing a main lamination process of applying pressure to the patterning film.

Step (B-1) may further include coating a release agent between the SR layer and the patterning film.

Step (C) may further include (C-1) etching the patterning film or the SR layer to respectively form openings in regions on which the plurality of SR posts are formed, to any one depth of a depth to which the openings are formed through the patterning film, a depth to which the openings are formed through the SR layer, and a predetermined depth of the SR layer; and (C-2) curing the patterning film.

The predetermined depth may be set in proportion to a height of each of the SR posts.

Step (D) may include (D-1) filling the SR ink in the openings by using a squeezing method using a squeeze or a rolling method using a roller; and (D-2) performing an exposure process on the SR ink filled in the opening to cure the SR ink.

The patterning film may include any one of a photo-resist film, a dry film, and a film formed of thermosetting resin.

Step (F) may include developing the uncured portion of the SR ink.

Step (G) may include sequentially performing a thermal drying process and a UV drying process.

According to a second preferred embodiment of the present invention, there is provided a method of manufacturing an electronic device package, including: (I) forming a solder resist (SR) layer on a printed circuit board; (II) integrally forming a plurality of SR posts on the SR layer; (III) connecting an electronic device chip to an upper portion of the plurality of SR posts and mounting the electronic device chip on an upper surface of the SR layer; and (IV) forming a molding portion of a molding material by molding the upper surface of the SR layer in addition to the electronic device chip.

Step (II) may include (II-1) disposing a patterning film on the upper surface of the SR layer; (II-2) etching the patterning film or the SR layer to respectively form openings in regions on which the plurality of SR posts are formed, to any one depth of a depth to which the openings are formed through the patterning film, a depth to which the openings are formed through the SR layer, and a predetermined depth of the SR layer; (II-3) forming a plurality of SR posts by filling SR ink in the openings and performing an exposure process on the SR ink; (II-4) delaminating the patterning film; (II-5) removing an uncured portion of the SR ink on which the exposure process is performed; and (II-6) drying the plurality of SR posts.

Step (II-1) may further include (II-11) tack-welding the patterning film on an upper surface of the SR layer by using a laminator; (II-12) removing a bubble between the SR layer and the patterning film by using a flattener; and (II-13) performing a main lamination process of applying pressure to the patterning film.

The predetermined depth of operation (II-2) may be set in proportion to a height of each of the SR posts.

Step (II-3) may include (II-31) filling the SR ink in the openings by using a squeezing method using a squeeze or a rolling method using a roller; and (II-32) performing an exposure process on the SR ink filled in the opening to cure the SR ink.

The patterning film may be any one of a photo-resist film, a dry film, and a film formed of thermosetting resin.

Step (II-5) may include developing the uncured portion of the SR ink.

Step (II-6) may include sequentially performing a thermal drying process and a UV drying process.

According to a third preferred embodiment of the present invention, there is provided an electronic device package including a printed circuit board disposed on an upper surface of a solder resist (SR) layer; a plurality of SR posts disposed on the SR layer; and an electronic device chip connected to an upper portion of the SR posts and mounted on the SR posts.

The SR posts may have a structure having any one depth of a depth to which the openings are formed through the patterning film, a depth to which the openings are formed through the SR layer, and a predetermined depth of the SR layer.

The predetermined depth may be set in proportion to a height of each of the SR posts.

The electronic device package may further include a molding portion for molding the upper surface of the SR layer in addition to the electronic device chip.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a cross-sectional view of an electronic device package including a solder resist (SR) post according to an embodiment of the present invention;

FIGS. 2A to 2D are cross-sectional views describing a method of forming a solder post (SR) post, according to an embodiment of the present invention;

FIGS. 3A to 3E are cross-sectional views for describing a method of forming SR posts, according to another embodiment of the present invention; and

FIG. 4 is a top view of a circuit board including SR posts, according to an embodiment of the present invention.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

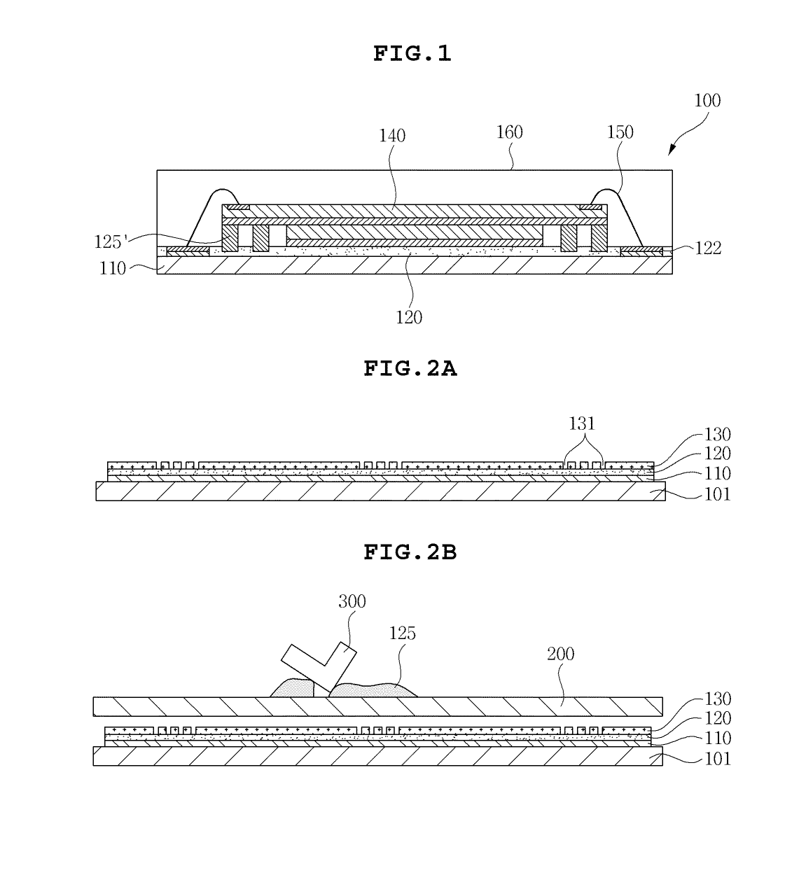

Hereinafter, preferred embodiments of the present invention will be described in detail with reference to the attached drawings. FIG. 1 is a cross-sectional view of an electronic device package 100 including a solder resist (SR) post according to an embodiment of the present invention.

The electronic device package 100 including the SR post according to the present embodiment includes a printed circuit board 110 having an upper surface whereon an SR layer 120 is disposed, a plurality of SR posts 125′ disposed on an upper surface of the SR layer 120, an electronic device chip 140 connected to an upper portion of the SR posts 125′ and mounted above the upper surface of the SR layer 120, and a molding portion 160 for molding the upper surface of the SR layer 120 in addition to the electronic device chip 140.

The printed circuit board 110 includes the SR layer 120 formed on an upper surface thereof, pads 122 connected to wires 150 and formed in at least two portions of the SR layer 120, and an interlayer circuit disposed in the printed circuit board 110. In this regard, the interlayer circuit may be formed by using, for example, a semi-additive process (AP), a modified semi-additive process (MSAP), or a subtractive process.

The plurality of SR posts 125′ may be formed in the SR layer 120 to have a predetermined depth and may be formed of solder resist that is the same as the SR layer 120 in a column form. The SR posts 125′ may be formed of a patterning film 130 that is described below in order to overcome problems of a conventional SR dam.

Thus, the SR posts 125′ may be formed to be higher than an SR dam instead of a conventional SR dam, and for example, may have a height of 70 μm or more.

The electronic device chip 140 is a chip obtained by attaching a die on the SR posts 125′ and mounted on the upper surface of the SR layer 120, and for example, is obtained by connecting and adhering a die, on which a semiconductor chip such as a system on chip (SoC) or a micro electro mechanical system (MEMS) chip is attached, to upper portions of the SR posts 125′. The electronic device chip 140 is electrically connected to the pads 122 of the printed circuit board 110 through the wires 150 and is encapsulated on the upper surface of the SR layer 120 by the molding portion 160 so as to be shielded and protected.

The electronic device package 100 may be mounted on other devices by using a plurality of solder disposed on a lower surface of the printed circuit board 110.

Thus, the electronic device package 100 according to the present embodiment is configured to package the electronic device chip 140 by using the SR posts 125′ without a conventional SR dam. Problems due to the conventional SR dam, such as process defects, warpage of a printed circuit board, solution contamination due to an excessive degree of SR development, or SR residues may be overcome.

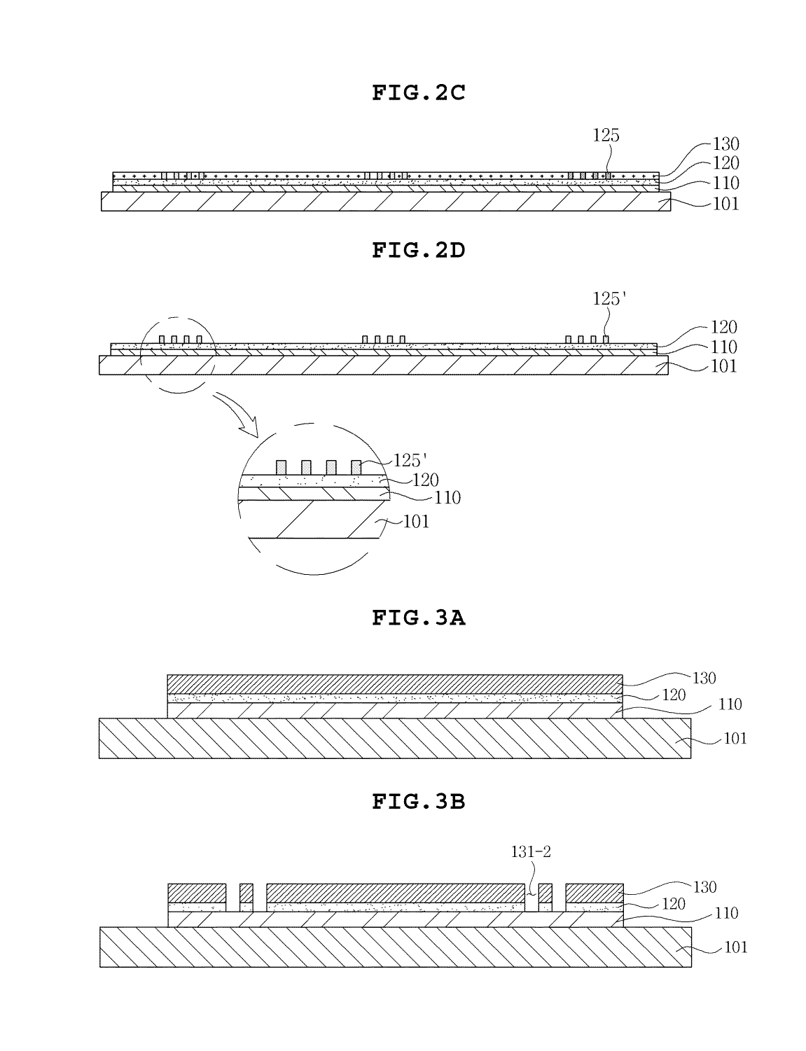

Hereinafter, a method of forming an SR post will be described with regard to an exemplary embodiment of the present invention with reference to FIGS. 2A to 2D. FIGS. 2A to 2D are cross-sectional views describing a method of forming an SR post, according to an embodiment of the present invention.

As shown in FIG. 2A, a method of manufacturing a printed circuit board according to an embodiment of the present invention includes forming the SR layer 120 on the printed circuit board 110 supported by a press forge 101 and disposing a patterning film 130 having openings 131 that are formed on the upper surface of the SR layer 120 so as to correspond to regions in which SR posts are to be formed.

In this case, the SR layer 120 may be formed by using a general method in which SR ink is coated on an upper surface of the printed circuit board 110 and exposing, developing, and drying an SR layer formed by coating the SR ink.

In addition, the patterning film 130 may be formed of synthetic resin such as polyethylene terephthalate (PET) or polyimide (PI) and may be formed to have the same height as the SR posts 125′ to be formed later.

In detail, the patterning film 130 having the openings 131 may be formed on the upper surface of the SR layer 120 by sequentially performing 1) a tack-welding process, 2) a flattener process, 3) a main lamination process, and 4) a process of forming openings.

1) The tack-welding process may be a process of tack-welding the patterning film 130 on the upper surface of the SR layer 120 and may be performed, for example, for 8 seconds at a temperature of 80° C.

2) The flattener process is a process of removing bubbles between the SR layer 120 and the patterning film 130 after the tacking-welding process is performed. Since there is no separate adhesive layer between the SR layer 120 and the patterning film 130, bubbles are removed by using a flattener to increase adhesion between the SR layer 120 and the patterning film 130. The flattener process may be performed, for example, at a pressure of 3.0 N/m² for 40 seconds. An optimum condition may be changed according to the material and thickness of the patterning film 130, the adhesion between the SR layer 120 and the patterning film 130, and so on.

3) The main lamination process is performed by applying a predetermined pressure for a predetermined period of time in order to further ensure the adhesion between the SR layer 120 and the patterning film 130 after the bubbles are removed by the flattener. In this case, the main lamination process may be performed at a pressure of 2.0 N/m² for 20 seconds. An optimum condition may be changed according to the material and thickness of the patterning film 130, the adhesion between the SR layer 120 and the patterning film 130, and so on.

4) The process of forming openings is a process of respectively forming the openings 131 in regions of the patterning film 130, in which the SR posts are to be formed, by, for example, a laser beam.

Selectively, the patterning film 130 may be adhered to the upper surface of the SR layer 120 and patterns of the patterning film 130 in which the openings 131 are previously formed may be formed on the upper surface of the SR layer 120 without forming the openings 131.

That is, the main lamination process may be performed by tack-welding the patterning film 130 having the openings 131 that are previously formed on the upper surface of the SR layer 120, closely attaching the SR layer 120 and the patterning film 130 to each other by removing bubbles between the SR layer 120 and the patterning film 130 by using a flattener, and applying pressure to the resulting structure. In this regard, in a process using the flattener, bubbles between the SR layer 120 and the patterning film 130 may be easily removed due to the openings 131 that are previously formed.

In addition, a release agent may be coated on the patterning film 130 on which the openings 131 are formed in order to easily perform a delamination process that will be described below.

Then, as shown in FIG. 2B, SR ink 125 in a liquid state is coated on the patterning film 130 having the openings 131 to be filled in the openings 131.

In detail, in order to coat the SR ink 125 on the patterning film 130, a screen printing method using a squeegee 300 and a plate 200 or a printing method using a roller may be used.

The screen printing method using the squeegee 300 and the plate 200 may be performed on the plate 200 having 200 mesh while the squeegee 300 is moved at a pressure of 0.4 Mpa and a speed of 75 mm/sec.

In the screen printing method using the squeeze 300 and the plate 200, a flattener may be used in order to reinforce filling the SR ink 125 in the openings 131.

In this case, the flattener may pressurize the upper surface of the patterning film 130 at a pressure of 3.0 N/m² for 40 seconds. An optimum condition may be changed according to the material and thickness of the patterning film 130.

After the SR ink 125 is filled in the openings 131, exposure is performed on the SR ink 125, as shown in FIG. 2C. In this case, the exposure may be, for example, ultraviolet (UV) rays and may change the SR ink 125 filled in the openings 131 to a curable crosslink state.

After the SR ink 125 of the openings 131 are changed to the curable crosslink state via the exposure, the patterning film 130 is delaminated, as shown in FIG. 2D. In this regard, a release agent that is selectively coated may facilitate the delamination of the patterning film 130.

After the patterning film 130 is delaminated, a development process and a final drying process for removing an uncured portion of the SR ink 125 are performed to form the SR posts 125′ that is completely cured.

In detail, the development process is performed in order to finally remove an uncured portion of the SR ink 125 after the patterning film 130 is delaminated. Via the development process, the uncured portion of the SR ink 125, which remains around the SR posts 125′, may be completely removed.

Then, the final drying process is performed to completely cure the SR posts 125′. In the final drying process, a thermal drying process at a temperature of 150° C. and a UV drying process of 1500 mJ may be sequentially performed.

The plurality of SR posts 125′ manufactured as described above are disposed on the upper surface of the SR layer 120, thereby preventing many problems that occur in terms of a conventional method, such as process defects, for example, damaged and rolled products, warpage of a printed circuit board, solution contamination due to an excessive degree of SR development, or SR residues.

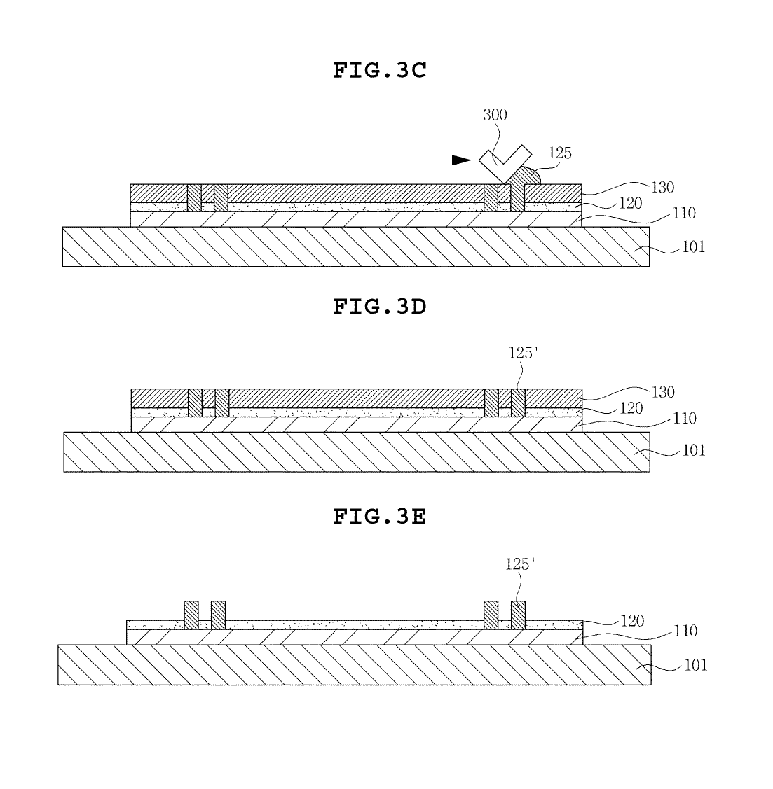

Hereinafter, a method of manufacturing a printed circuit board including an SR post will be described with regard to another exemplary embodiment of the present invention with reference to FIGS. 3A to 3E. FIGS. 3A to 3E are cross-sectional views for describing a method of forming the SR posts 125′, according to another embodiment of the present invention. The method shown in FIGS. 3A to 3E are different from the method shown in FIGS. 2A to 2D in that openings for forming the SR posts 125′ are formed through the SR layer 120 or are formed to a predetermined depth.

As shown in FIG. 3A, a method of manufacturing a printed circuit board according to another embodiment of the present invention includes forming the SR layer 120 on the printed circuit board 110 supported by a press forge 101 and disposing the patterning film 130 on an upper surface of the SR layer 120. In this case, the SR layer 120 may be formed by using a general method in which SR ink is coated on an upper surface of the printed circuit board 110 and exposing, developing, and drying an SR layer formed by coating the SR ink.

The patterning film 130 may be any one of a photo-resist film, a dry film, and a film formed of thermosetting resin such as polyethylene terephthalate (PET) or polyimide (PI). In addition, the thickness of the patterning film 130 may be determined in consideration of heights of the SR posts 125′ to be formed later.

In this case, the patterning film 130 may be disposed on the upper surface of the SR layer 120 by sequentially performing i) a tack-welding process, ii) a flattener process, and iii) a main lamination process.

In detail, i) the tack-welding process is a process in which the patterning film 130 is tack-welded on the upper surface of the SR layer 120 by using a laminator and may be performed, for example, for 8 seconds at a temperature of 80° C.

ii) The flattener process is a process of removing bubbles between the SR layer 120 and the patterning film 130 after the tacking-welding process is performed. Since there is no separate adhesive layer between the SR layer 120 and the patterning film 130, bubbles are removed by using a flattener to increase adhesion between the SR layer 120 and the patterning film 130. The flattener process may be performed, for example, at a pressure of 3.0 N/m² for 40 seconds. An optimum condition may be changed according to the material and thickness of the patterning film 130, the adhesion between the SR layer 120 and the patterning film 130, and so on.

iii) The main lamination process is performed by applying a predetermined pressure for a predetermined period of time in order to further ensure the adhesion between the SR layer 120 and the patterning film 130 after the bubbles are removed by the flattener. In this case, the main lamination process may be performed by using the laminator at a pressure of 2.0 N/m² for 20 seconds. An optimum condition may be changed according to the material and thickness of the patterning film 130, the adhesion between the SR layer 120 and the patterning film 130, and so on.

In this case, when the patterning film 130 is formed, a release agent may be coated between the SR layer 120 and the patterning film 130 in order to easily perform a delamination process on the patterning film 130, which will be described below.

After the patterning film 130 is laminated, a plurality of openings 131-2 are formed to a predetermined depth of the SR layer 120 through the patterning film 130, as shown in FIG. 3B.

In this case, the depth of the openings 131-2 may be determined in proportion to the height of the SR posts 125′ to be formed later. Since the heights of the SR posts 125′ are increased, a depth may be achieved such that the openings 131-2 may be formed through the SR layer 120. That is, as the heights of the SR posts 125′ is increased, the SR posts 125′ may be formed in the openings 131-2 through the SR layer 120 in order to reinforce support of the SR posts 125′.

Thus, the depths of the openings 131-2 in the SR layer 120 may be determined according to the material and height of the SR posts 125′, an optical amount of a laser beam, and an emission time of a laser beam.

Then, the patterning film 130 in which the openings 131-2 are formed may be cured by applying light such as UV or heat.

Accordingly, since the patterning film 130 in which the openings 131-2 are formed has strength via a curing process, the patterning film 130 may function as a patterning mask during a squeezing process for filling the SR ink 125 in the openings 131-2 that will be described below.

After the patterning film 130 is cured, the SR ink 125 in a liquid state is squeezed on an upper surface of the patterning film 130 in which the openings 131-2 are formed to be filled in the openings 131-2, as shown in FIG. 3C.

In detail, in order to fill the SR ink 125 in the openings 131-2, a squeezing method using the squeeze 300 or a rolling method using a roller may be used.

In particular, for example, in the squeezing method using the squeeze 300, the SR ink 125 is may be filled in the openings 131-2 by squeezing the SR ink 125 on the upper surface of the patterning film 130 by the squeeze 300 at a pressure of 0.4 Mpa and a speed of 75 mm/sec.

In the squeezing method using the squeeze 300, a flattener may be used in order to ensure filling the SR ink 125 in the openings 131-2.

For example, after the SR ink 125 is filled in the openings 131-2, the flattener may pressurize the upper surface of the patterning film 130 at a pressure of 3.0 N/m² for 40 seconds. An optimum condition may be changed according to the material and thickness of the patterning film 130.

After the SR ink 125 is filled in the openings 131-2, exposure is performed on the SR ink 125 filled in the openings 131-2, as shown in FIG. 3D. In this case, the exposure may use, for example, UV rays and may change the SR ink 125 filled in the openings 131-2 to a curable crosslink state.

Accordingly, coupling between the SR posts 125′ and the SR layer 120 may be reinforced such that the SR posts 125′ may be integrated with the SR layer 120.

After the SR ink 125 of the openings 131-2 are changed to the SR posts 125′ in the curable crosslink state via the exposure, the patterning film 130 is delaminated, as shown in FIG. 3E. In this regard, a release agent that is selectively coated between the SR layer 120 and the patterning film 130 may facilitate the delamination of the patterning film 130.

As the patterning film 130 is delaminated, the SR posts 125′ integrated with the SR layer 120 is exposed, as shown in FIG. 3E.

A development process and a final drying process for removing an uncured portion are performed on the SR layer 120 integrated with the SR posts 125′ to form the SR posts 125′ that are completely cured.

In detail, the development process is performed in order to finally remove an uncured portion of the SR ink 125 after the patterning film 130 is delaminated. Via the development process, the uncured portion of the SR ink 125, which remains around the SR posts 125′, may be completely removed.

Then, the final drying process is performed to completely cure the SR posts 125′. In the final drying process, a thermal drying process at a temperature of 150° C. and a UV drying process of 1500 mJ may be sequentially performed.

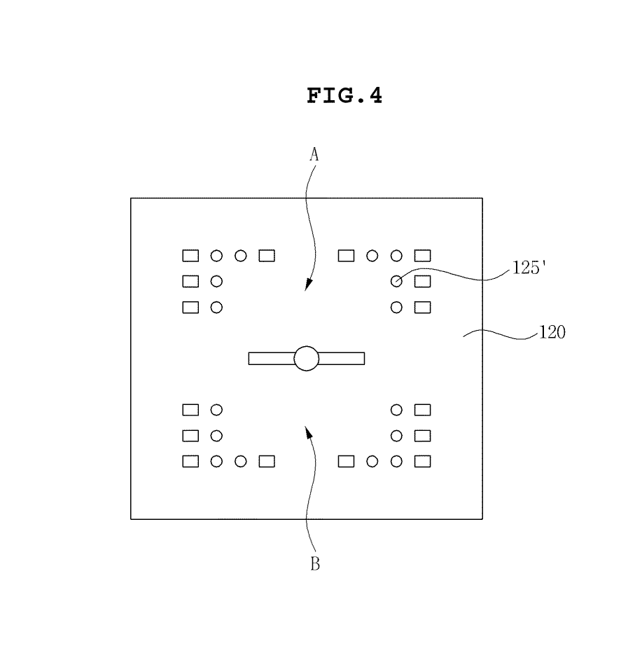

A printed circuit board including the plurality of SR posts 125′ manufactured as described above may be configured like in FIG. 4. In each of “A” and “B” regions, the electronic device chip 140 may be mounted on the SR posts 125 so as to be packaged.

That is, a packaging process of packaging the electronic device chip 140 in each of the “A” and “B” regions is performed on the printed circuit board including the plurality of SR posts 125′ shown in FIG. 4, thereby completing manufacture of the electronic device package 100 shown in FIG. 1.

For example, in each of the “A” and “B” regions of the printed circuit board manufactured as described above, the electronic device chip 140 is disposed on the SR posts 125′ and is mounted on the upper surface of the SR layer 120. The electronic device chip 140 may be a chip including, for example, a die. The die may be attached on the SR posts 125′ and may be mounted on the upper surface of the SR layer 120.

After the electronic device chip 140 is mounted, the electronic device chip 140 may be electrically connected to the pads 122 of the printed circuit board 110 through the wires 150.

Then, the molding portion 160 is formed of a molding material by molding the upper surface of the SR layer 120 in addition to the electronic device chip 140.

Thus, by using the printed circuit board including the plurality of SR posts 125′ manufactured by using the method according to the present embodiment, an electronic device package in which the electronic device chip 140 is double-packaged may be manufactured.

When the method of manufacturing a printed circuit board according to the present invention is used, the printed circuited board may overcome problems that arise due to an SR dam during a conventional method of manufacturing a printed circuit board, for example, process defects such as damaged and rolled products, warpage of the printed circuit board, solution contamination due to an excessive degree of SR development, or SR residues, thereby obtaining reliability.

When the method of manufacturing an electronic device package according to the present invention is used, the electronic device chip 140 is double-packaged by using the SR posts 125′, thereby overcoming process defects due to a conventional SR dam, warpage of the printed circuit board, solution contamination due to an excessive degree of SR development, or SR residues.

A method of forming an SR post according to the present invention may overcome problems that arise due to an SR dam during a conventional method of manufacturing a printed circuit board, for example, process defects such as damaged and rolled products, warpage of a printed circuit board, solution contamination due to an excessive degree of SR development, or SR residues.

In a method of manufacturing an electronic device package according to the present invention, an electronic device chip is packaged by using an SR post, thereby overcoming process defects due to a conventional SR dam, warpage of a printed circuit board, solution contamination due to an excessive degree of SR development, or SR residues.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A method of forming a solder resist (SR) post, the method comprising:
(A) forming an SR layer on a printed circuit board;
(B) disposing a patterning film on an upper surface on the SR layer;
(C) forming a plurality of openings in the patterning film or the SR layer;
(D) filling SR ink in the openings and performing an exposure process to form a plurality of SR posts;
(E) delaminating the patterning film;
(F) removing an uncured portion of the SR ink on which the exposure process is performed; and
(G) drying the plurality of SR posts.

2. The method as set forth in claim 1, wherein operation (B) includes:
(B-1) tack-welding the patterning film on an upper surface of the SR layer by using a laminator;
(B-2) removing a bubble between the SR layer and the patterning film by using a flattener; and
(B-3) performing a main lamination process of applying pressure to the patterning film.

3. The method as set forth in claim 2, wherein operation (B-1) further comprises coating a release agent between the SR layer and the patterning film.

4. The method as set forth in claim 1, wherein operation (C) further includes:
(C-1) etching the patterning film or the SR layer to respectively form openings in regions on which the plurality of SR posts are formed, to any one depth of a depth to which the openings are formed through the patterning film, a depth to which the openings are formed through the SR layer, and a predetermined depth of the SR layer; and
(C-2) curing the patterning film.

5. The method as set forth in claim 4, wherein the predetermined depth is set in proportion to a height of each of the SR posts.

6. The method as set forth in claim 1, wherein operation (D) includes:
(D-1) filling the SR ink in the openings by using a squeezing method using a squeeze or a rolling method using a roller; and
(D-2) performing an exposure process on the SR ink filled in the opening to cure the SR ink.

7. The method as set forth in claim 1, wherein the patterning film is any one of a photo-resist film, a dry film, and a film formed of thermosetting resin.

8. The method as set forth in claim 1, wherein operation (F) includes developing the uncured portion of the SR ink.

9. The method as set forth in claim 1, wherein operation (G) includes sequentially performing a thermal drying process and a UV drying process.

10. A method of manufacturing an electronic device package, the method comprising:
(I) forming a solder resist (SR) layer on a printed circuit board;
(II) integrally forming a plurality of SR posts on the SR layer;
(III) connecting an electronic device chip to an upper portion of the plurality of SR posts and mounting the electronic device chip on an upper surface of the SR layer; and
(IV) forming a molding portion of a molding material by molding the upper surface of the SR layer in addition to the electronic device chip.

11. The method as set forth in claim 10, wherein operation (II) includes:
(II-1) disposing a patterning film on the upper surface of the SR layer;
(II-2) etching the patterning film or the SR layer to respectively form openings in regions on which the plurality of SR posts are formed, to any one depth of a depth to which the openings are formed through the patterning film, a depth to which the openings are formed through the SR layer, and a predetermined depth of the SR layer;
(II-3) forming a plurality of SR posts by filling SR ink in the openings and performing an exposure process on the SR ink;
(II-4) delaminating the patterning film;
(II-5) removing an uncured portion of the SR ink on which the exposure process is performed; and
(II-6) drying the plurality of SR posts.

12. The method as set forth in claim 11, wherein operation (II-1) further includes:
(II-11) tack-welding the patterning film on an upper surface of the SR layer by using a laminator;
(II-12) removing a bubble between the SR layer and the patterning film by using a flattener; and
(II-13) performing a main lamination process of applying pressure to the patterning film.

13. The method as set forth in claim 11, wherein the predetermined depth of operation (II-2) is set in proportion to a height of each of the SR posts.

14. The method as set forth in claim 11, wherein operation (II-3) includes:
(II-31) filling the SR ink in the openings by using a squeezing method using a squeeze or a rolling method using a roller; and
(II-32) performing an exposure process on the SR ink filled in the opening to cure the SR ink.

15. The method as set forth in claim 11, wherein the patterning film is any one of a photo-resist film, a dry film, and a film formed of thermosetting resin.

16. The method as set forth in claim 11, wherein operation (II-5) includes developing the uncured portion of the SR ink.

17. The method as set forth in claim 11, wherein operation (II-6) includes sequentially performing a thermal drying process and a UV drying process.

18. An electronic device package comprising:
a printed circuit board disposed on an upper surface of a solder resist (SR) layer;
a plurality of SR posts disposed on the SR layer; and
an electronic device chip connected to an upper portion of the SR posts and mounted on the SR posts.

19. The electronic device package as set forth in claim 18, wherein the SR posts have a structure having any one depth of a depth to which the openings are formed through the patterning film, a depth to which the openings are formed through the SR layer, and a predetermined depth of the SR layer.

20. The electronic device package as set forth in claim 19, wherein the predetermined depth is set in proportion to a height of each of the SR posts.

21. The electronic device package as set forth in claim 18, further comprising a molding portion for molding the upper surface of the SR layer in addition to the electronic device chip.
